(19) United States
(12) Patent Application Publication
(10) Pub. No.: US 2014/0111067 A1
(43) Pub. Date: Apr. 24, 2014

(54) Front Case and LCD Device Using the Same

(71) Applicant: Yanxue Zhang, Shenzhen City (CN)

(72) Inventor: Yanxue Zhang, Shenzhen City (CN)

(73) Assignee: SHENZHEN CHINA STAR OPTOELECTRONICS TECHNOLOGY CO. LTD., Shenzhen, Guangdong (CN)

(21) Appl. No.: 13/699,700

(22) PCT Filed: Oct. 26, 2012
(86) PCT No.: PCT/CN2012/083607

§ 371 Date: Nov. 23, 2012

(30) Foreign Application Priority Data
Oct. 18, 2012 (CN) 201210397106.0

(51) Int. Cl. H05K 5/00

(52) U.S. Cl. CPC H05K 5/0017
USPC 312/7.2

(57) ABSTRACT

The present invention discloses a front case for assembling with a display module of an LCD device, and the front case is a hollow shell body formed by four side plates, the front case comprising: an inner baffle plate and an outer baffle plate mutually parallel and perpendicularly extended from both sides of each of the side plates, and the inner baffle plate and the outer baffle plate are disposed at the same surface of the front case; multiple hooks disposed on one of the side plates for fixing to the display module; and multiple compensation plates disposed at the inner baffle plate corresponding to the side plate having the hooks for compensating a curve bending caused by assembly of the hooks and the display module so that a contact surface between the front case and a display panel of the display module is flat. The present invention also provides an LCD device using the above front case. According to the present invention, it can maintain the flatness of the edge of the front case, reducing appearance deformation of the front case of the television after assembly, and reducing the gap between the front case and the display panel of the display module.

The claims of this application have submitted to the State Intellectual Property Office of the People's Republic of China (SIPO) on Oct. 18, 2012, Application No. 201210397106.0. The priority right based on the China application has a title of “a front case and an LCD device using the same”. The entire contents of the above-mentioned patent application will be incorporated in the present application through citing.

### BACKGROUND OF THE INVENTION

1. Field of the Invention

The present invention relates to a thin film transistor liquid crystal display (TFT-LCD) technology, and particularly to a front case and an LCD device using the same.

2. Description of Related Art

In the prior art, the display module of the thin-film transistor (TFT) liquid crystal display (LCD) device requires to assemble a front case to form a complete LCD device.

The front case 1 of some LCD devices typically uses hooks or screws to assemble with a display module 2. As shown in FIG. 1 and FIG. 2, this assembly method will occur the following state: because the front case 1 is usually made of a plastic sheet or metal foil and the hooks 10 are assembled with the display module 2, the pressure at the assembly portions (the portions of the hooks of the front case) will be relatively higher. The portion of the front case 1 between the two adjacent hooks 10 will generate a curve bending 11. The curve bending 11 will produce big gap 3 between the front case 1 and the LCD panel of the display module 2. It easily allows dust following into the interior of the TV and will affect the appearance of the LCD device.

### SUMMARY OF THE INVENTION

The technical problem to be solved by the present invention is to provide a front case and an LCD device. Through depositing compensation plates at the front case for compensating a curve bending caused by assembly of the front case and the display module, it can maintain the flatness of the edge of the front case, and reducing the gap between the front case and the display panel of the display module.

To solve the above technical problems, the present invention provides a front case for assembling with a display module of an LCD device, and the front case is a hollow shell body formed by four side plates, the front case comprising: an inner baffle plate and an outer baffle plate mutually parallel and perpendicularly extended from both sides of each of the side plates, and the inner baffle plate and the outer baffle plate are disposed at the same surface of the front case; multiple hooks disposed on one of the side plates for fixing to the display module; and a compensation plate disposed at a position of the inner baffle plate corresponding to a position between the two adjacent hooks, and the compensation plate is a convex curve structure extending out from the inner baffle plate for compensating a curve bending caused by assembly of the hooks and the display module so that a contact surface between the front case and a display panel of the display module is flat.

Wherein, the four side plates of the front case comprise a bottom side plate, and the hooks and the compensation plate are disposed on the bottom side plate.

Wherein, the four side plates of the front case comprise a bottom side plate, and the hooks and the compensation plate are disposed on the bottom side plate and on at least one of the other side plates.

Correspondingly, another embodiment of the present invention provides a front case for assembling with a display module of an LCD device, and the front case is a hollow shell body formed by four side plates, the front case comprising: an inner baffle plate and an outer baffle plate mutually parallel and perpendicularly extended from both sides of each of the side plates, and the inner baffle plate and the outer baffle plate are disposed at the same surface of the front case; multiple hooks disposed on one of the side plates for fixing to the display module; and multiple compensation plates disposed at the inner baffle plate corresponding to the side plate having the hooks for compensating a curve bending caused by assembly of the hooks and the display module so that a contact surface between the front case and a display panel of the display module is flat.

Wherein, the compensation plates disposed at positions of the inner baffle plate corresponding to positions between the two adjacent hooks.

Wherein, each of the compensation plates is a convex curve structure extending out from the inner baffle plate.

Wherein, the four side plates of the front case comprise a bottom side plate, and the hooks and the compensation plates are disposed on the bottom side plate.

Wherein, the four side plates of the front case comprise a bottom side plate, and the hooks and the compensation plates are disposed on the bottom side plate.

Wherein, the four side plates of the front case comprise a bottom side plate, and the hooks and the compensation plates are disposed on the bottom side plate.

Wherein, the four side plates of the front case comprise a bottom side plate, and the hooks and the compensation plates are disposed on the bottom side plate and on at least one of the other side plates.

Wherein, the four side plates of the front case comprise a bottom side plate, and the hooks and the compensation plates are disposed on the bottom side plate and on at least one of the other side plates.

Wherein, the four side plates of the front case comprise a bottom side plate, and the hooks and the compensation plates are disposed on the bottom side plate and on at least one of the other side plates.

Correspondingly, another embodiment of the present invention provides an LCD device comprising: a display module; and a front case for assembling with the display module, and the front case is a hollow shell body formed by four side plates, the front case comprising: an inner baffle plate and an outer baffle plate mutually parallel and perpendicularly extended from both sides of each of the side plates, and the inner baffle plate and the outer baffle plate are disposed at the same surface of the front case; multiple hooks disposed on one of the side plates for fixing to the display module; and multiple compensation plates disposed at the inner baffle plate corresponding to the side plate having the hooks for compensating a curve bending caused by assembly of the hooks and the display module so that a contact surface between the front case and a display panel of the display module is flat.

Wherein, the compensation plates disposed at positions of the inner baffle plate corresponding to positions between the two adjacent hooks.

Wherein, each of the compensation plates is a convex curve structure extending out from the inner baffle plate.

Wherein, the four side plates of the front case comprise a bottom side plate, and the hooks and the compensation plates are disposed on the bottom side plate.

Wherein, the four side plates of the front case comprise a bottom side plate, and the hooks and the compensation plates are disposed on the bottom side plate.

Wherein, the four side plates of the front case comprise a bottom side plate, and the hooks and the compensation plates are disposed on the bottom side plate.

Wherein, the four side plates of the front case comprise a bottom side plate, and the hooks and the compensation plates are disposed on the bottom side plate and on at least one of the other side plates.

Wherein, the four side plates of the front case comprise a bottom side plate, and the hooks and the compensation plates are disposed on the bottom side plate and on at least one of the other side plates.

Implementation of the embodiments of the present invention has the following beneficial effects:

Through depositing compensation plates at the inner baffle plate corresponding to the side plate having the hooks for compensating a curve bending caused by assembly of the hooks and the display module so that a contact surface between the front case and a display panel of the display module is flat so as to reduce appearance deformation of the front case of the television after assembly, and to reduce the gap between the front case and the display panel of the display module.

### BRIEF DESCRIPTION OF THE DRAWINGS

In order to more clearly illustrate the technical solution in the present invention or in the prior art, the following will illustrate the figures used for describing the embodiments or the prior art. It is obvious that the following figures are only some embodiments of the present invention. For the skilled persons of ordinary skill in the art without creative effort, it can also obtain other figures according to these figures.

FIG. 1 is an assembly schematic view of the display module and the front case in the prior art;

FIG. 2 is a front schematic view of the LCD device after assembly in FIG. 1;

FIG. 3 is a schematic view of a front case according to an embodiment of the present invention;

FIG. 4 is a schematic assembly view of the display module and the front case according to an embodiment of the present invention; and

FIG. 5 is a front schematic view of the LCD device after assembly in FIG. 4.

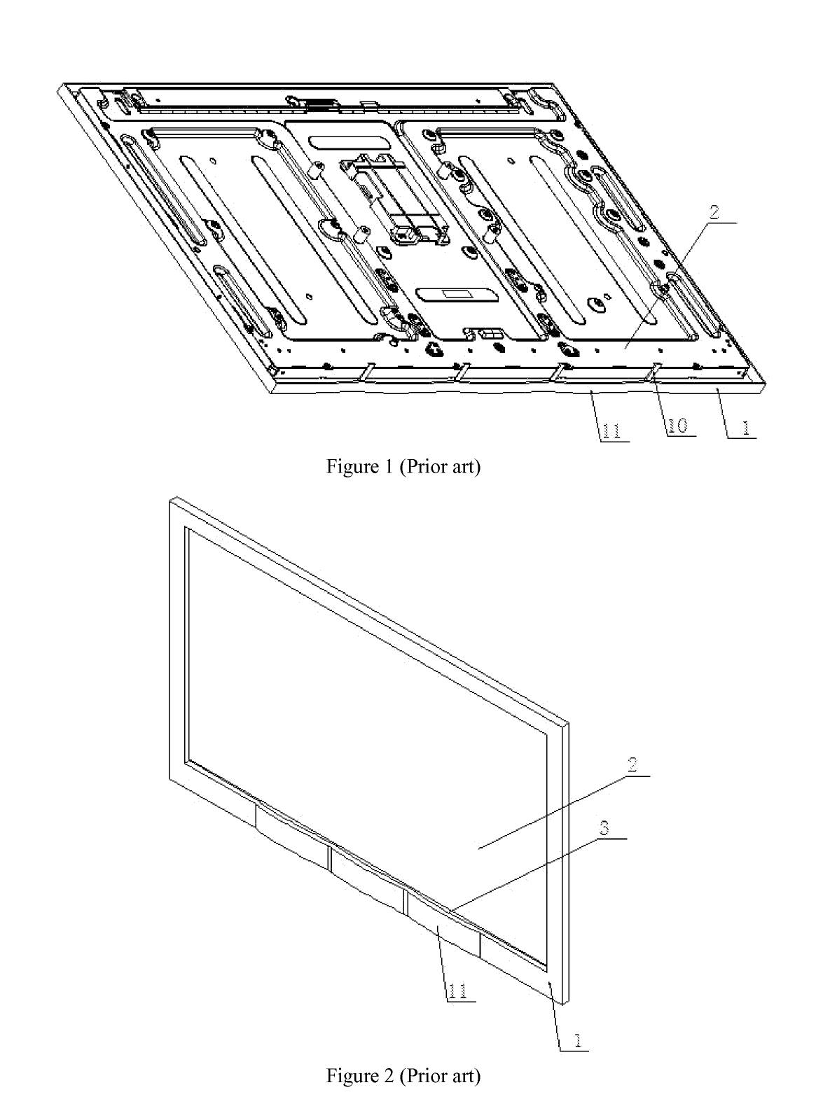

### DETAILED DESCRIPTION OF THE PREFERRED EMBODIMENT

The following content combines the drawings for describing preferred embodiments of the present invention.

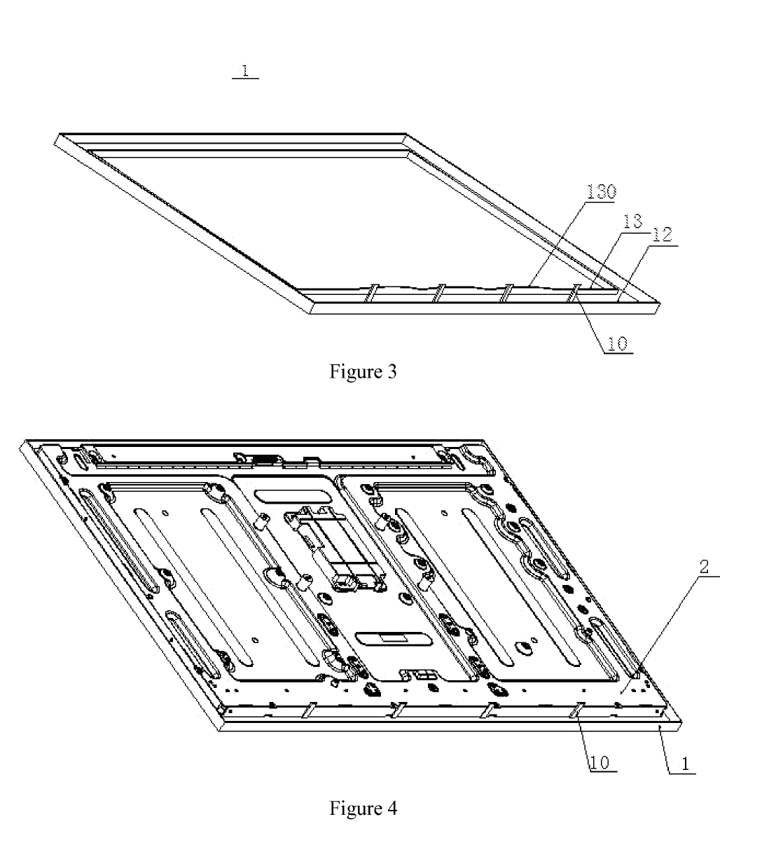

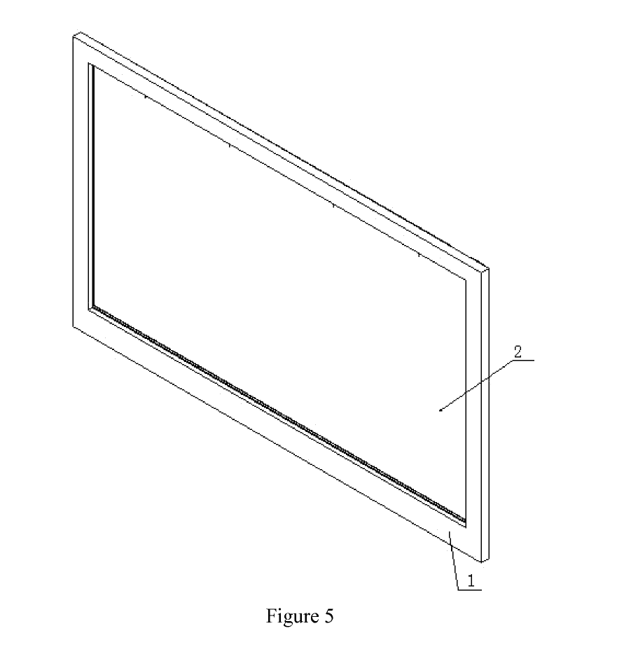

With reference to FIG. 3 to FIG. 5, it shows a schematic view according to an embodiment of the present invention. Wherein, a front case 1 is used for assembling with a display module 2. The front case 1 is a hollow shell body formed by four side plates. At the same surface of the front case (rear surface for example), each of the side plates perpendicularly extend an inner baffle plate 13 and an outer baffle plate 12 which are mutually parallel and disposed at both sides of the side plate. At least one side plate provides with multiple hooks 10, and the hooks 10 are used for fixing to the display module 2. For the convenience of description, it only shows that the hooks 10 are disposed on the base plate in FIG. 3. It can be understood that similar hooks 10 may be disposed at the other side plates;

Multiple compensation plates 130 are disposed at the corresponding inner baffle plate 13 of the side plate having the hooks 10 for compensating curve bending caused by assembly of the hooks 10 and the display module 2 so that a contact surface between the front case 1 and the display panel of the display module 2 is flat.

Wherein, the compensation plate 130 is a convex curve structure extending out from the inner baffle plate 13. Positions of the inner baffle plate 13 corresponding to a position between two adjacent hooks 10 are all provided with the compensation plates 130. When the hooks are assembled, the compensation plate 130 having a convex curve structure can compensate the curve bending of the side plate cause by assembly so as to maintain the flatness of the edge of the front case, reduce appearance deformation of the front case of the television after assembly, and to reduce the gap between the front case and the display panel of the display module.

It can be understood that in one embodiment, the hooks 10 and the compensation plates 130 are disposed on the bottom side plates of the front case 1, and the disposition method is described previously.

In another embodiment, the hooks 10 and the compensation plates 130 can be also disposed on at least one of the other side plates (the left side plate, the right side plate, the top side plate) as previously described.

Wherein, the number of the compensation plates 130 and the size of the convex curve structure depend on the structure and the disposition of the hooks 10, for example, the pitches of the hooks 10 or the engagement degree of the hooks 10.

Similarly, the present invention also provides a LCD device including a display module and a front case before assembling to the display module. Wherein, the front case and characteristics of it can refer to the description of FIG. 3 to FIG. 5, which does not repeat again.

It can be understood that the front case of the present invention can be applied to a LCD TV. Wherein, the structure of the front case and the assembly detail with the display module of the LCD TV can refer to the foregoing description of FIG. 3 to FIG. 5, which does not repeat again.

Implementation of the embodiments of the present invention has the following beneficial effects:

Through depositing compensation plates at the inner baffle plate corresponding to the side plate having the hooks for compensating a curve bending caused by assembly of the hooks and the display module so that a contact surface between the front case and a display panel of the display module is flat so as to reduce appearance deformation of the front case of the television after assembly, and to reduce the gap between the front case and the display panel of the display module.

The above content combines the preferred embodiments for detail description of the present invention. It is particularly pointed out that the above embodiments are only used to illustrate the present invention, and they are not used to limit the scope of the present invention. Other embodiments obtained under the premise of without paying creative labor by the person ordinary skill in the art are all belong to the claims of the present invention.

What is claimed is:

1. A front case for assembling with a display module of an LCD device, and the front case is a hollow shell body formed by four side plates, the front case comprising:
an inner baffle plate and an outer baffle plate mutually parallel and perpendicularly extended from both sides of each of the side plates, and the inner baffle plate and the outer baffle plate are disposed at the same surface of the front case;
multiple hooks disposed on one of the side plates for fixing to the display module; and
a compensation plate disposed at a position of the inner baffle plate corresponding to a position between the two adjacent hooks, and the compensation plate is a convex curve structure extending out from the inner baffle plate for compensating a curve bending caused by assembly of the hooks and the display module so that a contact surface between the front case and a display panel of the display module is flat.

2. The front case according to claim 1, wherein, the four side plates of the front case comprise a bottom side plate, and the hooks and the compensation plate are disposed on the bottom side plate.

3. The front case according to claim 1, wherein, the four side plates of the front case comprise a bottom side plate, and the hooks and the compensation plate are disposed on the bottom side plate and on at least one of the other side plates.

4. A front case for assembling with a display module of an LCD device, and the front case is a hollow shell body formed by four side plates, the front case comprising:
an inner baffle plate and an outer baffle plate mutually parallel and perpendicularly extended from both sides of each of the side plates, and the inner baffle plate and the outer baffle plate are disposed at the same surface of the front case;
multiple hooks disposed on one of the side plates for fixing to the display module; and
multiple compensation plates disposed at the inner baffle plate corresponding to the side plate having the hooks for compensating a curve bending caused by assembly of the hooks and the display module so that a contact surface between the front case and a display panel of the display module is flat.

5. The front case according to claim 4, wherein, the compensation plates disposed at positions of the inner baffle plate corresponding to positions between the two adjacent hooks.

6. The front case according to claim 5, wherein, each of the compensation plates is a convex curve structure extending out from the inner baffle plate.

7. The front case according to claim 4, wherein, the four side plates of the front case comprise a bottom side plate, and the hooks and the compensation plates are disposed on the bottom side plate.

8. The front case according to claim 5, wherein, the four side plates of the front case comprise a bottom side plate, and the hooks and the compensation plates are disposed on the bottom side plate.

9. The front case according to claim 6, wherein, the four side plates of the front case comprise a bottom side plate, and the hooks and the compensation plates are disposed on the bottom side plate.

10. The front case according to claim 4, wherein, the four side plates of the front case comprise a bottom side plate, and the hooks and the compensation plates are disposed on the bottom side plate and on at least one of the other side plates.

11. The front case according to claim 5, wherein, the four side plates of the front case comprise a bottom side plate, and the hooks and the compensation plates are disposed on the bottom side plate and on at least one of the other side plates.

12. The front case according to claim 6, wherein, the four side plates of the front case comprise a bottom side plate, and the hooks and the compensation plates are disposed on the bottom side plate and on at least one of the other side plates.

13. An LCD device comprising:
a display module; and
a front case for assembling with the display module, and the front case is a hollow shell body formed by four side plates, the front case comprising:
an inner baffle plate and an outer baffle plate mutually parallel and perpendicularly extended from both sides of each of the side plates, and the inner baffle plate and the outer baffle plate are disposed at the same surface of the front case;
multiple hooks disposed on one of the side plates for fixing to the display module; and
multiple compensation plates disposed at the inner baffle plate corresponding to the side plate having the hooks for compensating a curve bending caused by assembly of the hooks and the display module so that a contact surface between the front case and a display panel of the display module is flat.

14. The front case according to claim 13, wherein, the compensation plates disposed at positions of the inner baffle plate corresponding to positions between the two adjacent hooks.

15. The front case according to claim 14, wherein, each of the compensation plates is a convex curve structure extending out from the inner baffle plate.

16. The front case according to claim 13, wherein, the four side plates of the front case comprise a bottom side plate, and the hooks and the compensation plates are disposed on the bottom side plate.

17. The front case according to claim 14, wherein, the four side plates of the front case comprise a bottom side plate, and the hooks and the compensation plates are disposed on the bottom side plate.

18. The front case according to claim 15, wherein, the four side plates of the front case comprise a bottom side plate, and the hooks and the compensation plates are disposed on the bottom side plate.

19. The front case according to claim 14, wherein, the four side plates of the front case comprise a bottom side plate, and the hooks and the compensation plates are disposed on the bottom side plate and on at least one of the other side plates.

20. The front case according to claim 15, wherein, the four side plates of the front case comprise a bottom side plate, and the hooks and the compensation plates are disposed on the bottom side plate and on at least one of the other side plates.
